(19) United States
(12) Patent Application Publication
(10) Pub. No.: US 2026/0114038 A1
(43) Pub. Date: Apr. 23, 2026

(54) SILICIDE REGIONS IN STACKED TRANSISTORS AND METHODS OF FORMING

(71) Applicant: Taiwan Semiconductor Manufacturing Co., Ltd., Hsinchu (TW)

(72) Inventors: Rui-Fu Chen, Hsinchu (TW); Hsin Yang Hung, New Taipei City (TW); Guan-Ren Wang, Hsinchu (TW); Shih-Jung Ho, Hsinchu (TW); Kuan-Kan Hu, Hsinchu (TW); Tsung-Kai Chiu, Hsinchu (TW); Wei-Xiang You, Kaohsiung (TW)

(21) Appl. No.: 19/170,309

(22) Filed: Apr. 4, 2025

Related U.S. Application Data
(60) Provisional application No. 63/709,005, filed on Oct. 18, 2024.

(51) Int. Cl. H10D 84/85; H10D 30/00; H10D 30/01; H10D 62/10

(52) U.S. Cl. CPC H10D 84/851; H10D 30/019; H10D 30/501; H10D 62/121; H10D 62/124

(57) ABSTRACT

A semiconductor device and the method of forming are provided. The semiconductor device may include a first dielectric layer, a first source/drain region in the first dielectric layer, a first nanostructure on a sidewall of the first source/drain region, a first gate structure around the first nanostructure, a first conductive contact electrically connected to the first source/drain region, and a first metal-semiconductor alloy region between the first portion of the first conductive contact and the first source/drain region. A first portion of the first conductive contact may extend through the first source/drain region, and the first portion of the first conductive contact comprises a first sidewall and a second sidewall opposite the first sidewall in a cross-sectional view. A first portion of the first metal-semiconductor alloy region may be on the first sidewall and a second portion of the first metal-semiconductor alloy region may be on the second sidewall.

### PRIORITY CLAIM AND CROSS-REFERENCE

This application claims the benefit of U.S. Provisional Application No. 63/709,005, filed on Oct. 18, 2024, which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example a stacking transistor in accordance with some embodiments.

FIGS. 2, 3, 4, 5A, 5B, 6A, 6B, 7A, 7B, 8A, 8B, 9A, 9B, 10A, 10B, 11A, 11B, 12A, and 12B are various views of intermediate stages in the manufacturing of a stacking transistor in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Various embodiments provide a semiconductor device and methods of forming the same. The semiconductor device may be a stacking transistor comprising an upper transistor and a lower transistor that are vertically stacked. The upper transistor and the lower transistor may include respective upper and lower semiconductor nanostructures, as well as upper and lower source/drain regions on sidewalls of the respective upper and lower semiconductor nanostructures. The semiconductor device may also include source/drain contacts that are electrically connected to the respective upper and lower source/drain regions. Metal-semiconductor alloy regions may be formed between the source/drain contacts and the respective upper and lower source/drain regions to reduce resistance between the source/drain contacts and the respective upper and lower source/drain regions. Selected source/drain contacts may be electrically connected to both the upper source/drain regions and lower source/drain regions by extending through the upper source/drain regions. Dielectric layers may be on upper sidewalls of the selected source/drain contacts. By forming the dielectric layers before extending openings through the upper source/drain regions, where the source/drain contacts may be formed, a risk of damaging the upper source/drain regions may be reduced, and areas of the upper metal-semiconductor alloy regions formed on the upper source/drain regions 62U may be increased. As a result, the performance and reliability of the stacking transistor may be improved.

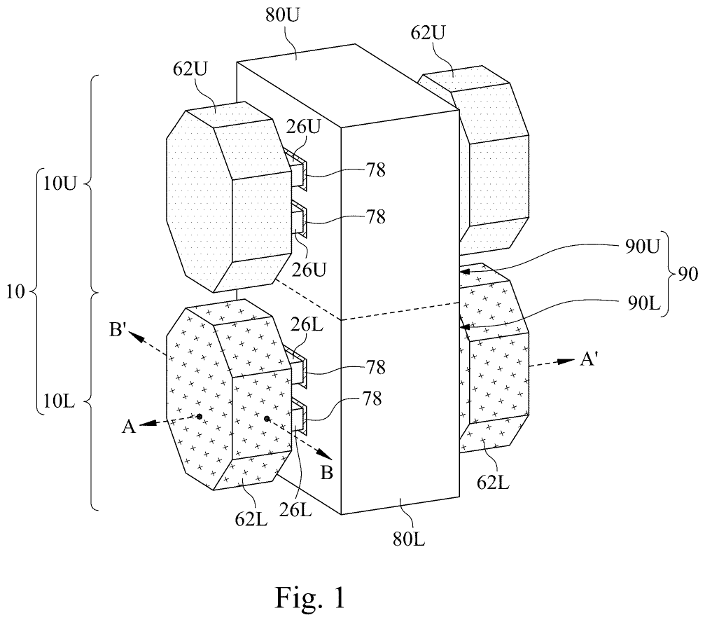

FIG. 1 illustrates an example of a stacking transistor 10 in accordance with some embodiments. FIG. 1 is a perspective view, and some features of the stacking transistor are omitted for illustration clarity. The stacking transistor includes multiple vertically stacked FETs. For example, a stacking transistor may include a lower nanostructure-FET 10L of a first device type (e.g., n-type or p-type) and an upper nanostructure-FET 10U of a second device type (e.g., p-type or n-type). When the stacking transistor is a Complementary Field-Effect Transistors (CFET), the second device type of the upper nanostructure-FET 10U is opposite to the first device type of the lower nanostructure-FET 10L. The upper nanostructure-FETs 10U and lower nanostructure-FET 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors, Nano Field-effect Transistors (nano-FETs), Fin Field Effect Transistors (finFETs), or the like.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower epitaxial source/drain regions 62L and upper epitaxial source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate selected ones of the source/drain regions 62 and/or selected ones of the gate electrodes 80.

FIG. 1 further illustrates reference cross-section A-A′ and B-B′. Reference cross-section A-A′ may be a vertical cross-section that is parallel to a longitudinal axis of the semiconductor nanostructures 26 of the stacking transistor 10 and in a direction of, for example, a current flow between the source/drain regions 62 of the stacking transistor 10. Reference cross-section B-B′ may be a vertical cross-section that is perpendicular to the reference cross-section A-A′ and extend through the source/drain regions 62. The reference cross-sections A-A′ and B-B′ in FIG. 1 may correspond to the reference cross-sections A-A′ and B-B′ shown in some of the subsequent top view figures.

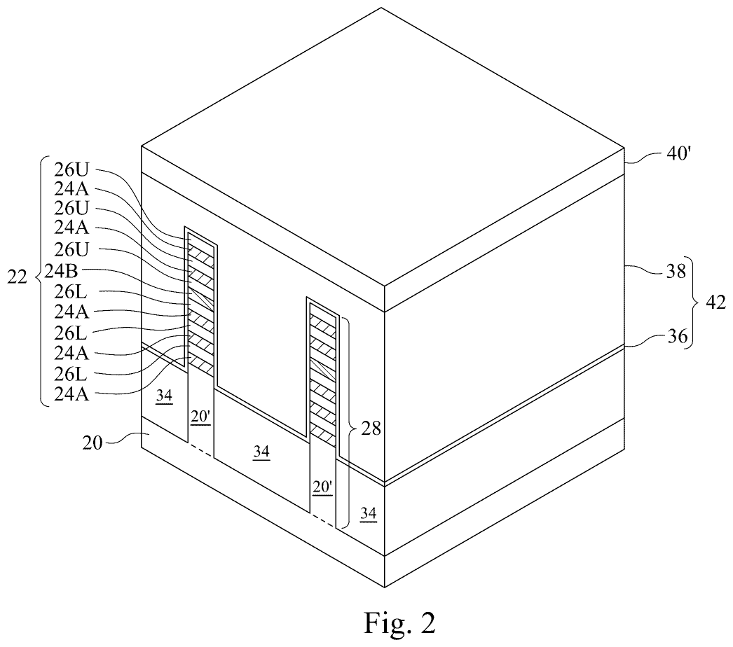

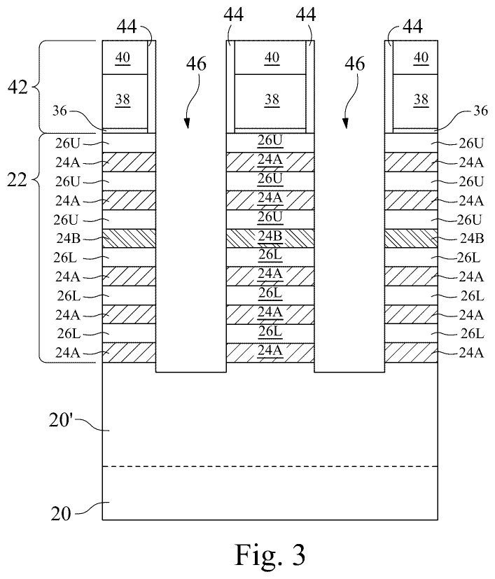

FIGS. 2 through 12B are various views of intermediate stages in the manufacturing of a stacking transistor including lower nanostructure-FETs and upper nanostructure-FETs, which may be similar to the stacking transistor 10 shown in FIG. 1, in accordance with some embodiments. FIG. 2 is a perspective view and FIGS. 3 through 12B are cross-sectional views of a portion of the structure shown in FIG. 2. In FIG. 2, a wafer, which includes substrate 20, is provided. The substrate 20 may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor, the like, or combinations thereof.

Semiconductor strips 28 are formed extending upwards from the substrate 20. Each of semiconductor strips 28 includes semiconductor fin 20′ (patterned portions of the substrate 20) and a multi-layer stack 22. The stacked component of the multi-layer stack 22 is referred to as nanostructures hereinafter. Specifically, the multi-layer stack 22 includes dummy nanostructures 24A, dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B is formed of a second semiconductor material different from the first semiconductor material. In some embodiments, the first semiconductor material is silicon germanium with a first germanium concentration and the second semiconductor material is silicon germanium with a second germanium concentration different from the first germanium concentration. The first and second semiconductor materials may be selected from the candidate semiconductor materials of the substrate 20. The first and second semiconductor materials have a high etching selectivity to one another. As such, the dummy nanostructures 24B may be removed at a faster rate than the dummy nanostructures 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructure 24 may be selectively removed in subsequent processes without significantly removing the semiconductor nanostructures 26. In some embodiments, the semiconductor nanostructures 26 are formed of silicon, the dummy nanostructures 24A are formed of silicon germanium, and the dummy nanostructures 24B are formed of germanium or silicon germanium with a higher germanium atomic percentage than the dummy nanostructures 24A.

The lower semiconductor nanostructures 26L may act as channel regions for lower nanostructure-FETs of the stacking transistor. The upper semiconductor nanostructures 26U may act as channel regions for upper nanostructure-FETs of the stacking transistor. The semiconductor nanostructures 26 that are immediately above/below (e.g., in contact with) the dummy nanostructures 24B may be used for isolation and may or may not act as channel regions for the stacking transistor. The dummy nanostructures 24B may be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the substrate 20 to define the semiconductor strips 28, which includes the semiconductor fins 20′, the dummy nanostructures 24, and the semiconductor nanostructures 26.

For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the substrate 20. The etching may be performed by any acceptable etch process, such as a Reactive Ion Etch (RIE), Neutral Beam Etch (NBE), the like, or a combination thereof. The etching may be anisotropic.

STI regions 34 are formed over the substrate 20 and between adjacent semiconductor strips 28. The STI regions 34 may be on sidewalls of the semiconductor fins 20′. The STI regions 34 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 34 may include depositing the dielectric layer(s), and performing a planarization process such as a Chemical Mechanical Polishing (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 34 include silicon oxide formed by an FCVD process, followed by an anneal process. Then, the dielectric liner and the dielectric material are recessed to define the STI regions 34, such that upper portions of semiconductor strips 28 (including multi-layer stacks 22) protrude higher than the remaining STI regions 34.

After the STI regions 34 are formed, dummy gate stacks 42 may be formed over and along sidewalls of the upper portions of the semiconductor strips 28 (the portions that protrude higher than the STI regions 34). Forming the dummy gate stacks 42 may include forming dummy dielectric layer 36 on the semiconductor strips 28 and forming a dummy gate layer 38 over the dummy dielectric layer 36. Dummy dielectric layer 36 may be formed of, for example, silicon oxide, silicon nitride, a combination thereof, or the like, and may be deposited or thermally grown according to acceptable techniques. The dummy gate layer 38 may be deposited, for example, through Physical Vapor Deposition (PVD), CVD, or other techniques, and then planarized, such as by a CMP process. The material of dummy gate layer 38 may be selected from a group including amorphous silicon, polycrystalline-silicon (polysilicon), poly-crystalline silicon-germanium (poly-SiGe), or the like.

A mask layer 40′ is formed over the planarized dummy gate layer 38. The mask layer 40′ may comprise, silicon nitride, silicon oxynitride, or the like. Then the mask layer 40′ may be patterned by suitable photolithography and etching processes to form a mask 40 (shown FIG. 3), which may be then used to pattern dummy gate layer 38 and the dummy dielectric layer 36. The mask 40, the remaining portions of the dummy gate layer 38, and the dummy dielectric layer 36 may be referred to as the dummy gate stacks 42.

In FIG. 3, gate spacers 44 and source/drain recesses 46 are formed. FIG. 3 may be obtained along a reference cross-section that corresponds to the reference cross-section A-A′ shown in FIG. 1. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. The mask 40, and the gate spacers 44 may be used to protect the dummy gate layers 38 during subsequent etching processes.

Subsequently, source/drain recesses 46 are formed in semiconductor strips 28. The source/drain recesses 46 are formed through etching, and may extend through the multi-layer stacks 22 and into the semiconductor fins 20′. The bottom surfaces of the source/drain recesses 46 may be at a level above, below, or level with the top surfaces of the STI regions 34 (not shown). In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a selected depth.

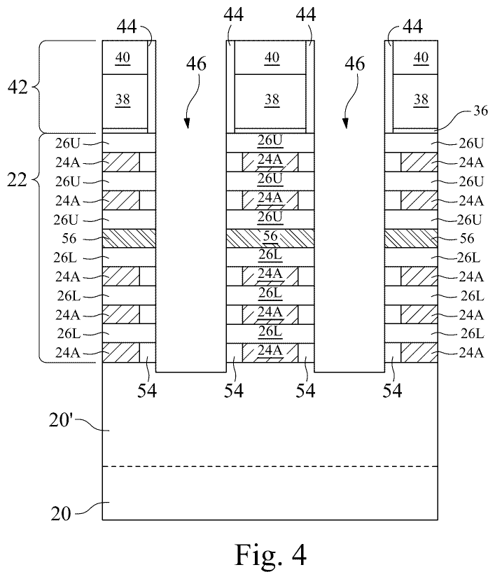

In FIG. 4, the dummy nanostructures 24A are partially removed and the dummy nanostructure 24B are completely removed. FIG. 4 may be obtained along a reference cross-section that corresponds to the reference cross-section A-A′ shown in FIG. 1. Then inner spacers 54 and dielectric isolation layers 56 are formed. After the dummy nanostructures 24A are partially removed, sidewalls of the dummy nanostructures 24A may be recessed. The dummy nanostructures 24A and the dummy nanostructure 24B may be removed by a suitable etching process. The etching process may selectively remove the materials of the dummy nanostructures 24A and the dummy nanostructure 24B without significantly removing the materials of the upper semiconductor nanostructures 26U, the lower semiconductor nanostructures 26L, or the semiconductor fins 20′. The etching process may remove the dummy nanostructures 24A at a slower rate than the dummy nanostructure 24B.

In the embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etching process may be a dry etching process using etchant(s), such as chlorine, and/or the like. Because the dummy gate stacks 42 warp around the sidewalls of the semiconductor nanostructures 26 (see FIG. 2), the dummy gate stacks 42 may support the upper semiconductor nanostructures 26U so that the upper semiconductor nanostructures 26U do not collapse upon the complete removal of the dummy nanostructures 24B.

The inner spacers 54 may be formed on the recessed sidewalls of the dummy nanostructures 24A. The dielectric isolation layers 56 may be formed in spaces the dummy nanostructures 24B occupied before being removed. Source/drain regions may be subsequently formed in the source/drain recesses 46, and the dummy nanostructures 24A may be replaced with corresponding gate structures. The inner spacers 54 may be used to isolate the subsequently formed source/drain regions from the subsequently formed gate structures. The dielectric isolation layers 56 may be used to isolate the upper semiconductor nanostructures 26U from the lower semiconductor nanostructures 26L.

The inner spacers 54 and the dielectric isolation layers 56 may be formed by conformally depositing a suitable dielectric material in the source/drain recesses 46, on the sidewalls the dummy nanostructures 24A, and between the bottom upper semiconductor nanostructures 26U and the top lower semiconductor nanostructures 26L. The dielectric material may be then etched to remove excess portions. The dielectric material may be a hard dielectric material, such as a carbon-containing dielectric material, such as silicon oxycarbonitride, silicon oxycarbide, silicon carbonitride, or the like. Other low-dielectric constant (low-k) materials having a k-value less than about 3.5 may be utilized. The dielectric material may be formed by a suitable deposition process, such as ALD, CVD, or the like. The etching of the dielectric material may be an anisotropic etching process or an isotropic etching process.

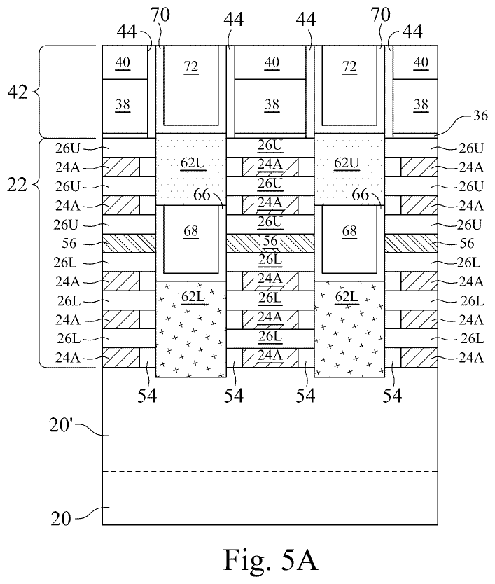

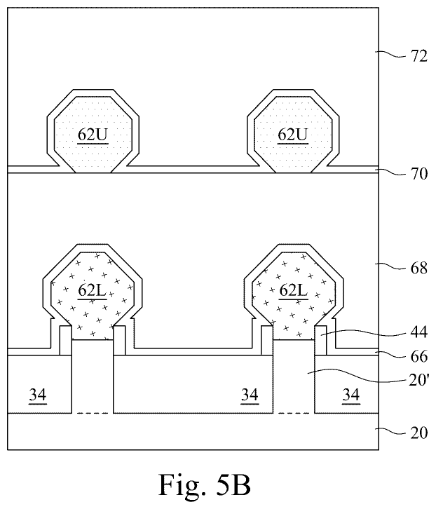

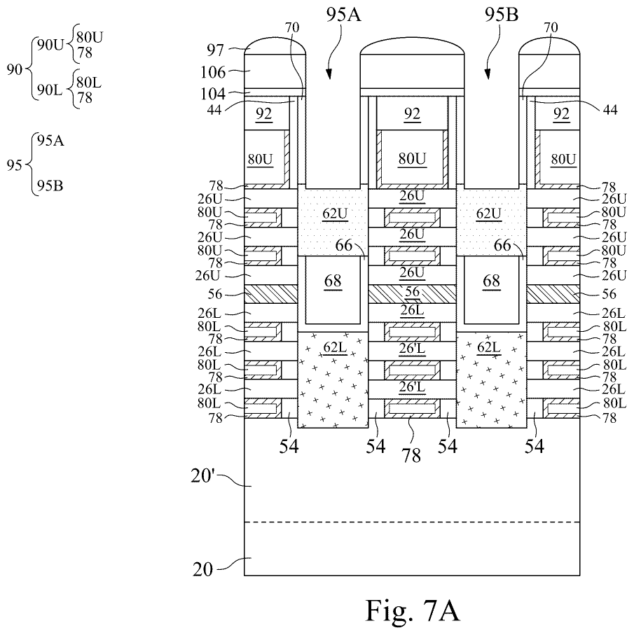

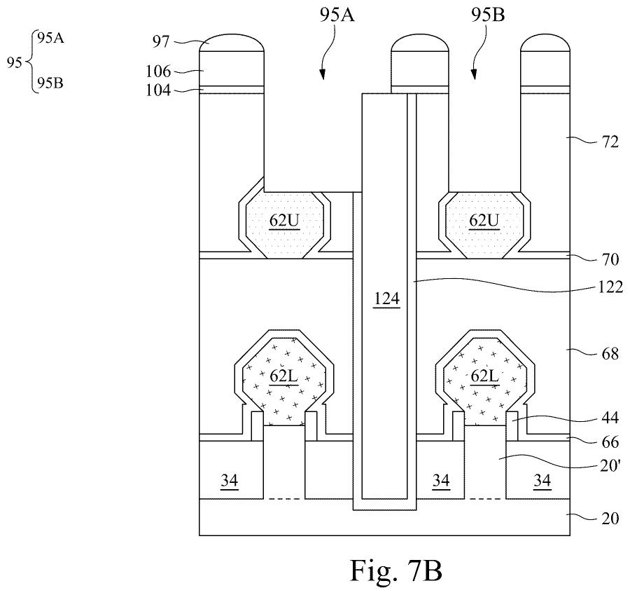

In FIGS. 5A and 5B, lower source/drain regions 62L, upper epitaxial source/drain regions 62U, first contact etch stop layers (CESLs) 66, first inter-layer dielectrics (ILDs) 68, second CESLs 70, and second ILDs 72 are formed in the source/drain recesses 46. FIGS. 5A and 5B are cross-sectional views of a same structure. FIG. 5A may be obtained along a reference cross-section that corresponds to the reference cross-section A-A′ shown in FIG. 1 and FIG. 7B may be obtained along a reference cross-section that corresponds to the reference cross-section B-B′ as shown in FIG. 1.

The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The upper epitaxial source/drain regions 62U are in contact with the upper semiconductor nanostructures 26U and are not in contact with the lower semiconductor nanostructures 26L. The lower epitaxial source/drain regions 62L are in contact with the inner spacers 54, which electrically insulate the lower epitaxial source/drain regions 62L from the dummy nanostructures 24A. The upper epitaxial source/drain regions 62U are in contact with inner spacers 54, which electrically insulate the upper epitaxial source/drain regions 62U from the dummy nanostructures 24A. The dummy nanostructures 24A will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L to merge.

The first CESLs 66 and the first ILDs 68 are formed over the lower epitaxial source/drain regions 62L. The first CESLs 66 may be formed of a dielectric material having a high etching selectivity from the etching of the first ILDs 68, such as silicon nitride, silicon oxide, silicon oxynitride, or the like, which may be formed by any suitable deposition process, such as CVD, ALD, or the like. The first ILDs 68 may be formed of a dielectric material, which may be deposited by any suitable method, such as CVD, plasma-enhanced CVD (PECVD), or FCVD. The applicable dielectric material of the first ILDs 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILDs 68, followed by a planarization process and then an etch-back process. In some embodiments, the first ILDs 68 are etched first, leaving the conformal CESL layer unetched. An anisotropic etching process is then performed to remove the portions of the conformal CESL layer higher than the recessed first ILDs 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower epitaxial source/drain regions 62L, depending on the selected conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant.

As a result of the epitaxy processes used for forming the upper epitaxial source/drain regions 62U, upper surfaces of the upper epitaxial source/drain regions 62U have facets which expand laterally outward beyond sidewalls of the multi-layer stacks 22. In some embodiments, adjacent upper epitaxial source/drain regions 62U remain separated after the epitaxy process is completed. In other embodiments, these facets cause neighboring upper epitaxial source/drain regions 62U to merge.

After the upper epitaxial source/drain regions 62U are formed, second CESLs 70 and second ILDs 72 are formed. The materials and the formation methods may be similar to the materials and the formation methods of the first CESLs 66 and the first ILDs 68, respectively. The formation process may include depositing the conformal CESL layer and the second ILDs 72, and performing a planarization process to remove the excess portion of the corresponding layers. After the planarization process, top surfaces of the second ILDs 72, the gate spacers 44, and mask 40 may be substantially coplanar (within process variations). In the illustrated embodiment, the mask 40 remain after the removal process. In other embodiments, the mask 40 are removed such that the top surfaces of the dummy gate layers 38 are exposed.

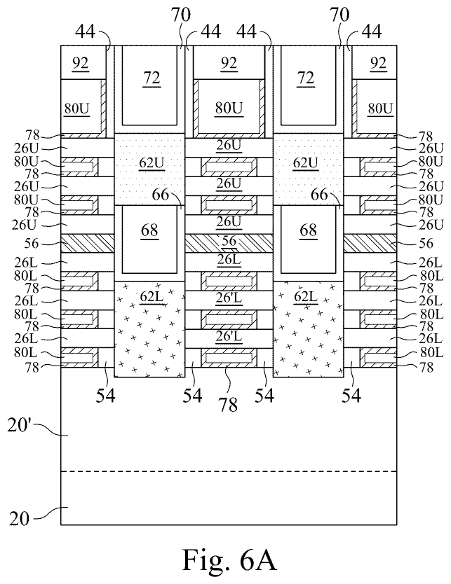

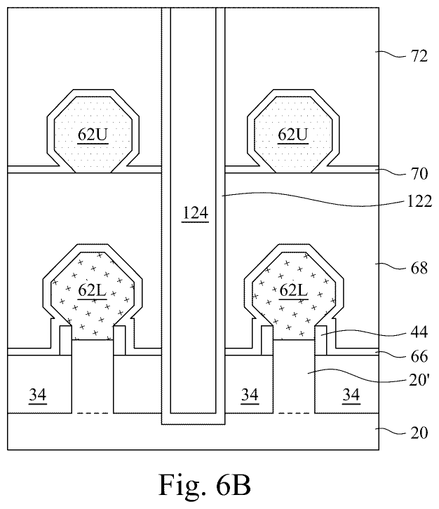

In FIGS. 6A and 6B, a gate replacement process to replace the dummy gate stacks 42 and the dummy nanostructures 24A with gate structures 90 is performed, then a dielectric liner 122 and a vertical interconnect 124 extending through the second ILDs 72, second CESLs 70, the first ILDs 68, first CESLs 66, and the STI regions 34 are formed. The vertical interconnect 124 may electrically connect subsequently formed source/drain contacts over the vertical interconnect 124 to conductive features (not shown) that may be formed on the side of the substrate 20. The cross-sectional view in FIG. 6A may correspond to the cross-sectional view shown in FIG. 5A and the cross-sectional view in FIG. 6B may correspond to the cross-sectional view shown in FIG. 5B.

The gate replacement process may include first removing the dummy gate stacks 42 and the dummy nanostructures 24A. The dummy gate stacks 42 may be removed by one or more suitable etching processes. The dummy nanostructures 24A may be then removed by an additional suitable etching process. The etching process that removes the dummy nanostructures 24A may selectively remove the material of the dummy nanostructures 24A without significantly removing the material(s) of the semiconductor nanostructures 26. In the embodiments where the dummy nanostructures 24A comprise silicon germanium, and the semiconductor nanostructures 26 comprise silicon, the etching process may be a wet isotropic etching process and etchants such as tetramethylammonium hydroxide, ammonium hydroxide, or the like may be used.

Then, gate dielectrics 78 may be deposited in the recesses between the gate spacers 44 and on the exposed semiconductor nanostructures 26. The gate dielectrics 78 may be conformally formed on the exposed surfaces of the recesses (the removed dummy gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the semiconductor fins 20′; on the top surfaces, the sidewalls, and the bottom surfaces of the semiconductor nanostructures 26; and on the sidewalls of the inner spacers 54.

The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILDs 72. Although single-layered gate dielectrics 78 may be illustrated, the gate dielectrics 78 may include multiple layers, such as an interfacial layer and an overlying high-k dielectric layer.

Lower gate electrodes 80L may be formed on the gate dielectrics 78 around the lower semiconductor nanostructures 26L. The lower gate electrodes 80L may wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material. The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

The lower gate electrodes 80L may be formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

In some embodiments, isolation layers (not illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Upper gate electrodes 80U may be formed on the isolation layers described above (if present) or the lower gate electrodes 80L. The upper gate electrodes 80U may be disposed between the upper semiconductor nanostructures 26U. In some embodiments, the upper gate electrodes 80U wrap around the upper semiconductor nanostructures 26U. The upper gate electrodes 80U may be formed of the same or similar materials and formed by same or similar processes as the lower gate electrodes 80L. The upper gate electrodes 80U may be formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered upper gate electrodes 80U are illustrated, the upper gate electrodes 80U may include any number of work function tuning layers, any number of barrier layers, any number of glue layers, and a fill material.

Gate masks 92 may be formed on the upper gate structures 90U. The formation process may include recessing the upper gate structures 90U, filling the resulting recesses with a dielectric material such as silicon nitride, silicon carbonitride, silicon oxynitride, silicon oxycarbonitride, or the like, and performing a planarization process to remove the excess portions of the dielectric material over the second ILDs 72 and to level top surfaces of the gate masks 92 and the second ILDs 72. The planarization process may be a CMP process, an etch-back process, combinations thereof, or the like. After the planarization process, the top surfaces of the gate masks 92, the gate dielectrics 78, the second ILDs 72, and the gate spacers 44 may be substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

Then an opening may be formed through the second ILDs 72, second CESLs 70, the first ILDs 68, first CESLs 66, and the STI regions 34. In some embodiments, the opening may be formed into the substrate 20. The dielectric liner 122. The opening may be formed by multiple etching processes using various etchants effective for the removal of the materials of the second ILDs 72, the second CESLs 70, the first ILD 68, the first CESL 66, and the STI region 34. The dielectric liner 122 and the vertical interconnect 124 may be formed in the opening, as shown in FIG. 6B. The dielectric liner 122 may cover surfaces of the opening and the vertical interconnect 124 may cover the surfaces of the dielectric liner 122 and fill in the rest of the space of the opening. The dielectric liner 122 may be formed of a suitable dielectric material, such as silicon oxide, silicon nitride, silicon oxynitride, silicon oxycarbonitride, or the like, and formed by a suitable deposition process, such as CVD, ALD, or the like. The vertical interconnect 124 may be formed of a suitable conductive material, such as cobalt, tungsten, molybdenum, copper, ruthenium, or the like and formed by a suitable deposition process, such as CVD, PVD, or the like. A planarization process, such as CMP, may be performed to remove excess dielectric and conductive materials formed during the deposition processes.

In FIGS. 7A and 7B, a third CESL 104 and a third ILD 106 are formed on the structure shown in FIGS. 6A and 6B, a mask 97 is formed on the third ILD 106, and openings 95 are formed through the third ILD 106, the third CESL 104, the second ILDs 72, and the second CESLs 70. The cross-sectional view in FIG. 7A may correspond to the cross-sectional view shown in FIG. 6A and the cross-sectional view in FIG. 7B may correspond to the cross-sectional view shown in FIG. 6B. The third CESL 104 may be formed on top surfaces of the second ILDs 72, the second CESLs 70, the gate spacers 44, the gate masks 92, the vertical interconnect 124, and the dielectric liner 122. The third CESL 104 may be formed of a same or similar material and formed by a same or similar process as the second CESLs 70. The third ILD 106 may be formed on a top surface of the third CESL 104. The third ILD 106 may be formed of a same or similar material and formed by a same or similar process as the second ILDs 72.

The mask 97 may be formed on a top surface of the third ILD 106. The mask 97 may comprise a suitable dielectric material. The mask 97 may be formed by a suitable deposition process and then patterned by a suitable photolithography process. Openings in the mask 97 may correspond to locations of the openings 95. The mask 97 may have rounded sidewalls adjacent the openings to provide ease of access to the features underneath the openings. Then the openings 95 may be formed through the openings in the mask 97. The openings 95 may comprise the openings 95A and the openings 95B. The openings 95B may be extended in subsequent etching processes while the openings 95A may be substantially intact in the subsequent etching processes.

The openings 95 may be formed by a series of etching processes, which may partially remove the third ILD 106, the third CESL 104, the second ILDs 72, the second CESLs 70, and the dielectric liner 122. The openings 95 may expose sidewalls of the mask 97, the third ILD 106, the third CESL 104, and the second ILDs 72, and upper surfaces of the upper epitaxial source/drain regions 62U. In some embodiments, the upper epitaxial source/drain regions 62U are partially removed, which results in the openings 95 extending into the upper epitaxial source/drain regions 62U and exposing sidewalls of the upper epitaxial source/drain regions 62U. In some embodiments, sidewalls of the second CESLs 70 are exposed by the openings 95. In some embodiments, as shown in FIG. 7B, upper surfaces of the second CESLs 70 are exposed by the openings 95. In some embodiments, as shown in FIG. 7B, a top surface and a sidewall of the vertical interconnect 124, and upper surfaces of the dielectric liner 122 and the second ILD 72 are exposed by some of the openings 95A.

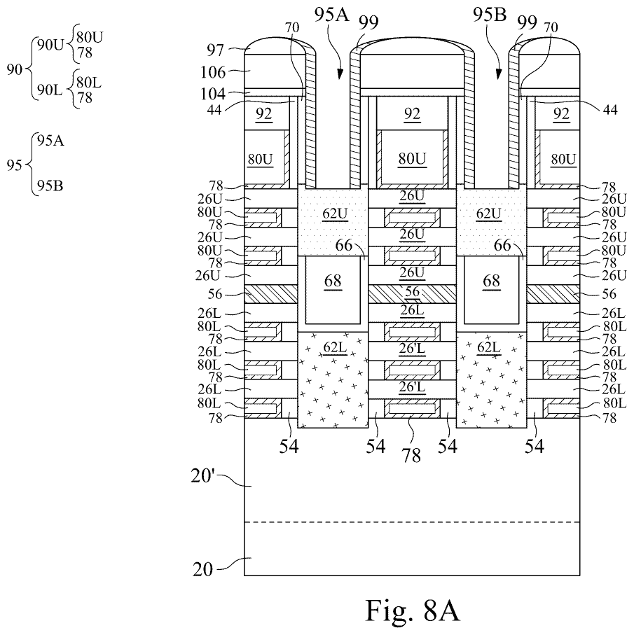

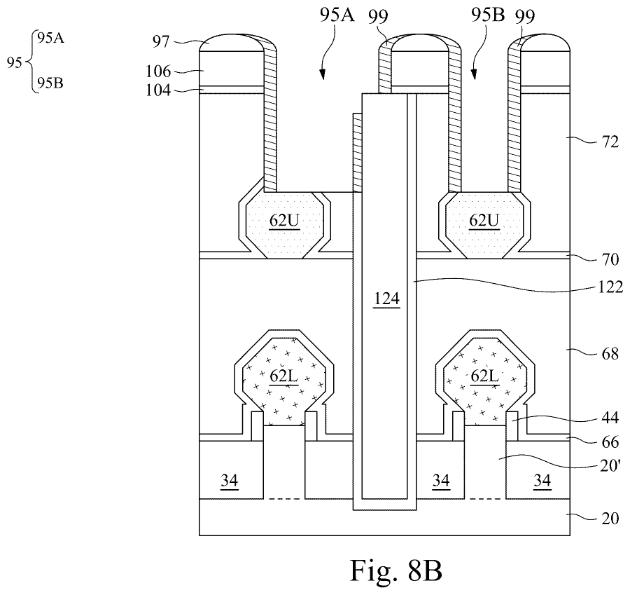

In FIGS. 8A and 8B, dielectric liners 99 are formed on sidewalls of the openings 95. The dielectric liners 99 may be also referred to as dielectric layers. The cross-sectional view in FIG. 8A may correspond to the cross-sectional view shown in FIG. 7A and the cross-sectional view in FIG. 8B may correspond to the cross-sectional view shown in FIG. 7B. The dielectric liners 99 may cover exposed sidewalls of the mask 97, the third ILD 106, the third CESL 104, the second ILDs 72, the second CESLs 70, and the vertical interconnect 124. In the embodiments where the openings 95 extend into the upper epitaxial source/drain regions 62U, the dielectric liners 99 cover exposed sidewalls of the upper epitaxial source/drain regions 62U. The dielectric liners 99 may comprise a dielectric material, such as silicon nitride or the like. In some embodiments, the dielectric liners 99 and the second CESLs 70 may comprise different materials.

The dielectric liners 99 may be formed by depositing a conformal dielectric layer in the openings 95 by a suitable deposition process, such as CVD, ALD, or the like, and then selectively removing horizontal portions of the dielectric layer by a suitable etching process, such as an anisotropic dry etching process, while vertical portions of the dielectric layer are substantially intact or at most partially removed. After the etching process, the sidewalls of the mask 97, the third ILD 106, the third CESL 104, and the second ILDs 72 may be covered by the remaining vertical portions of the dielectric layer, which may be referred to as the dielectric liners 99, while the upper surfaces of the upper epitaxial source/drain regions 62U are exposed after the etching process. By forming the dielectric liners 99 before a subsequent step where the openings 95B are extended deeper, removing the horizontal portions of the conformal dielectric layer at a greater depth with a harsher etching process may be avoided, which may reduce a risk of damaging the upper epitaxial source/drain regions 62U.

In the embodiments where the sidewalls of the upper epitaxial source/drain regions 62U are exposed by the openings 95, the sidewalls of the upper epitaxial source/drain regions 62U are covered by the dielectric liners 99 after the etching process. In the embodiments where the sidewalls of the second CESLs 70 are exposed by the openings 95, the sidewalls of the second CESLs 70 are covered by the dielectric liners 99 after the etching process. In the embodiments where upper surfaces of the second CESLs 70 are exposed by the openings 95, as shown in FIG. 8B, the upper surfaces of the second CESLs 70 in the openings 95A remain exposed and the upper surfaces of the second CESLs 70 in the openings 95B are at least partially covered by the dielectric liners 99 after the etching process. In the embodiments where the top surface and the sidewall of the vertical interconnect 124, and the upper surfaces of the dielectric liner 122 and the second ILDs 72 are exposed by some of the openings 95A, as shown in FIG. 8B, the upper surface of the dielectric liner 122 and the sidewall of the vertical interconnect 124 are at least partially covered by the dielectric liners 99, and the top surface of the vertical interconnect 124 and the upper surface of the second ILD 72 remain exposed after the etching process.

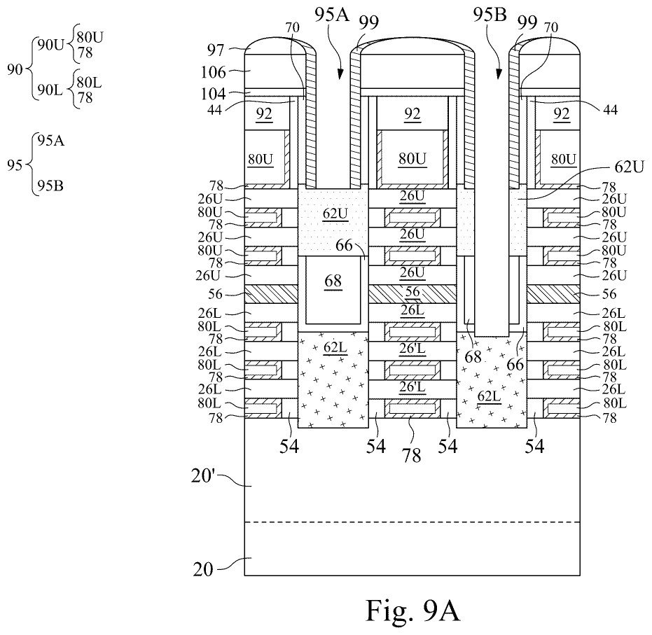

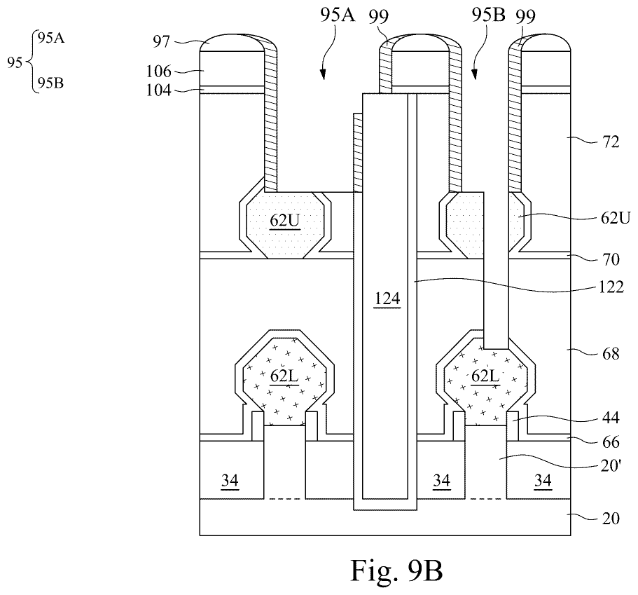

Subsequently, in FIGS. 9A and 9B, the openings 95B are extended to extend through the upper epitaxial source/drain regions 62U, the first ILDs 68, the first CESLs 66 to expose the lower epitaxial source/drain regions 62L. The cross-sectional view in FIG. 9A may correspond to the cross-sectional view shown in FIG. 8A and the cross-sectional view in FIG. 9B may correspond to the cross-sectional view shown in FIG. 8B. The openings 95B may be extended by a series of etching processes, which may partially remove the upper epitaxial source/drain regions 62U, the first ILDs 68, the first CESLs 66. During the series of etching processes, the openings 95A may be protected by a photoresist or another mask (not shown), which may be removed after the series of etching processes.

The extended openings 95B may expose sidewalls of upper epitaxial source/drain regions 62U, the first ILDs 68, and the first CESLs 66, and the upper surfaces of the lower epitaxial source/drain regions 62L. By forming the dielectric liners 99 before the extending the openings 95B, the dielectric liners 99 may not extend through the upper epitaxial source/drain regions 62U and may remain above the first ILDs 68. As a result, the sidewalls of upper epitaxial source/drain regions 62U may be exposed and metal-semiconductor alloy regions may be formed on the exposed sidewalls of upper epitaxial source/drain regions 62U in a subsequent process. In some embodiments, the lower epitaxial source/drain regions 62L are partially removed, which results in the openings 95B extending into the lower epitaxial source/drain regions 62L and exposing sidewalls of the lower epitaxial source/drain regions 62L. In some embodiments, as shown in FIG. 9B, a portion of the second CESL 70 underneath the upper epitaxial source/drain region 62U is removed, and a sidewall of the second CESL 70 is exposed.

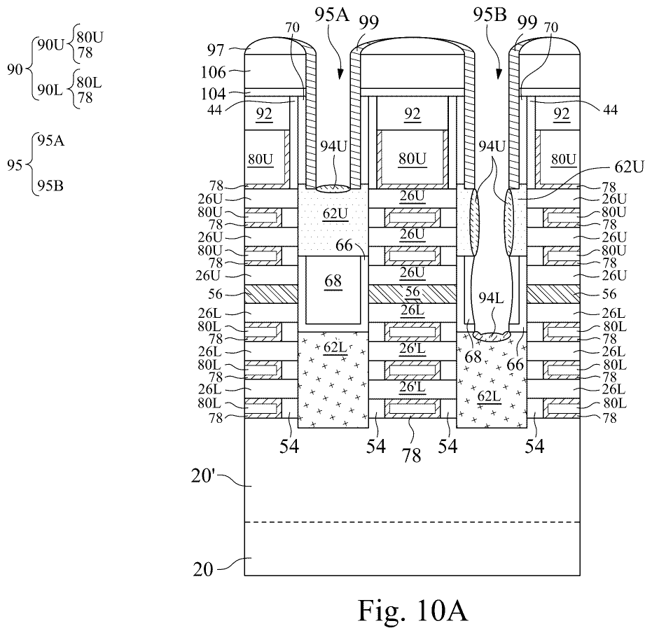

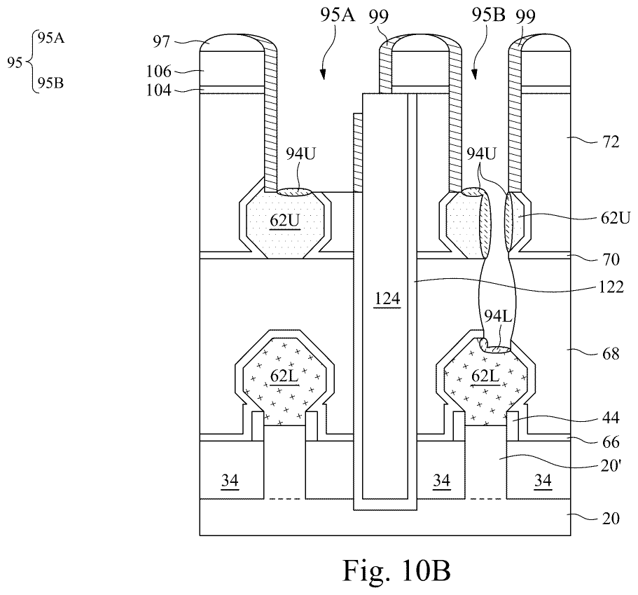

In FIGS. 10A and 10B, upper metal-semiconductor alloy regions 94U and lower metal-semiconductor alloy regions 94L are formed on exposed surfaces of the upper epitaxial source/drain regions 62U and the lower epitaxial source/drain regions 62L, respectively. The upper metal-semiconductor alloy regions 94U and the lower metal-semiconductor alloy regions 94L may be collectively referred to as the metal-semiconductor alloy regions 94. The metal-semiconductor alloy regions 94 may comprise a material with low resistance, which may reduce the resistance between the source/drain regions 62 and the subsequently formed source/drain contacts. The cross-sectional view in FIG. 10A may correspond to the cross-sectional view shown in FIG. 9A and the cross-sectional view in FIG. 10B may correspond to the cross-sectional view shown in FIG. 9B.

The metal-semiconductor alloy regions 94 may have curved surfaces, such as convex surfaces. In the openings 95A, the upper metal-semiconductor alloy regions 94U may cover the upper surfaces of the upper epitaxial source/drain regions 62U. In the openings 95B, the upper metal-semiconductor alloy regions 94U may cover the upper surfaces and the sidewalls of the upper epitaxial source/drain regions 62U, and the lower metal-semiconductor alloy regions 94L may cover the upper surfaces and the sidewalls of the lower epitaxial source/drain regions 62L. Since the openings 95B extend through the upper epitaxial source/drain regions 62U and expose the sidewalls of the upper epitaxial source/drain regions 62U, areas of the upper metal-semiconductor alloy regions 94U may be increased, which may further the resistance between the upper epitaxial source/drain regions 62U and the subsequently formed source/drain contacts. In the embodiments where the sidewalls of the lower epitaxial source/drain regions 62L are exposed, the lower metal-semiconductor alloy regions 94L may cover the sidewalls of the lower epitaxial source/drain regions 62L.

The metal-semiconductor alloy regions 94 may be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 94 may be formed by depositing a metal layer in the openings 95 and then performing an annealing process. The metal layer may comprise a material capable of reacting with the semiconductor materials (e.g., silicon, silicon-germanium, germanium, etc.) of the source/drain regions 62 to form a metal-semiconductor alloy, such as nickel, cobalt, titanium, tantalum, platinum, tungsten, alloys thereof, or the like. The metal layer may be deposited by a suitable deposition process, such as ALD, CVD, PVD, or the like.

During the annealing process portions of the source/drain regions 62 may react with portions of the metal layer to generate the metal-semiconductor alloy regions 94. After the annealing process, a cleaning process, such as a wet etching process, may be performed to remove remaining portions of the metal layer from the openings 95. In the openings 95B, the first ILDs 68 may be partially removed during the cleaning process at the exposed sidewalls of the first ILDs 68. As a result, the sidewalls of the first ILDs 68 may be concave after the cleaning process.

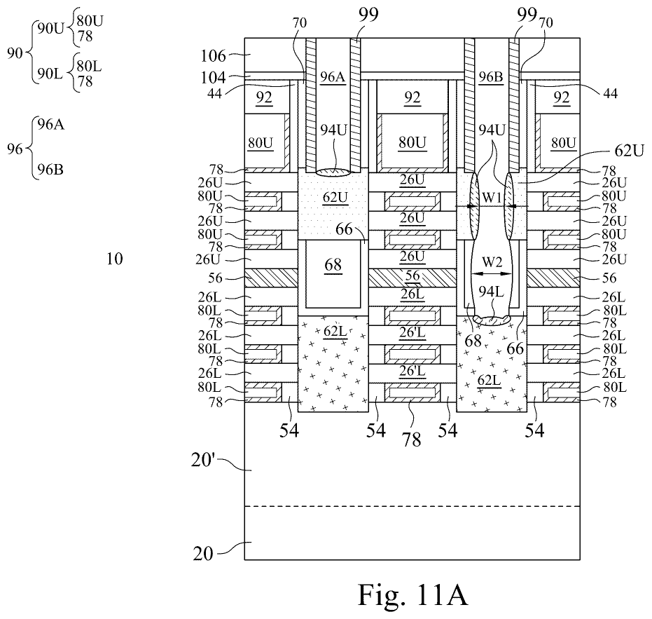

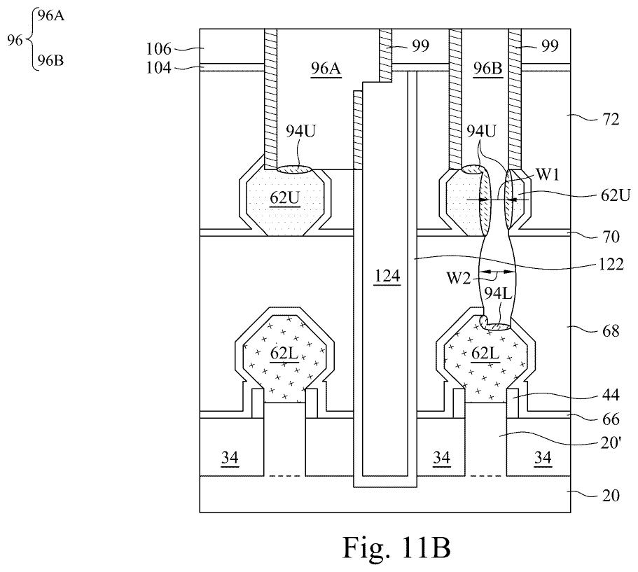

In FIGS. 11A and 11B, source/drain contacts 96 are formed in the openings 95 and the mask 97 is removed. The source/drain contacts 96 may comprise the source/drain contacts 96A formed in the openings 95A and the source/drain contacts 96B formed in the openings 95B. The cross-sectional view in FIG. 11A may correspond to the cross-sectional view shown in FIG. 10A and the cross-sectional view in FIG. 11B may correspond to the cross-sectional view shown in FIG. 10B. The source/drain contacts 96 may fill in the spaces of the openings 95 and cover the surfaces exposed by the openings 95. The source/drain contacts 96 may be separated from and electrically connected to the source/drain regions 62 by the metal-semiconductor alloy regions 94.

The source/drain contacts 96B may extend through the upper epitaxial source/drain regions 62U. Portions of the source/drain contacts 96B in the source/drain regions 62U may be encircled by the upper metal-semiconductor alloy regions 94U, and the upper metal-semiconductor alloy regions 94U may be encircled by the upper epitaxial source/drain regions 62U in a top view. The increased areas of the upper metal-semiconductor alloy regions 94U may reduce the resistance between the source/drain contacts 96B and the upper epitaxial source/drain regions 62U, as well as the current crowding effect in the upper epitaxial source/drain regions 62U. As a result, the performance and reliability of the subsequently formed stacking transistor may be improved.

The source/drain contacts 96B may extend through the first ILDs 68. Portions of the source/drain contacts 96B in the first ILDs 68 may be encircled by the first ILDs 68 in the top view. The portions of the source/drain contacts 96B in the source/drain regions 62U may have concave sidewalls and a width W1. The portions of the source/drain contacts 96B in the first ILDs 68 may have convex sidewalls and a width W2. The width W2 may be larger than the width W1. The portions of the source/drain contacts 96B in the first ILDs 68 may have an increased width due to the partial removal of the first ILDs 68 in a previous cleaning process. As a result, the portions of the source/drain contacts 96B in the first ILDs 68 may have reduced resistance, which may also improve the performance and reliability of the subsequently formed stacking transistor.

The source/drain contacts 96 may be formed by depositing a conductive material in the openings 95 by a suitable deposition process, such as ALD, CVD, PVD, or the like. The conductive material may be cobalt, tungsten, copper, silver, gold, aluminum, nickel, or the like. In some embodiments, a conductive liner is deposited in the openings 95 before depositing the conductive material. A planarization process, such as CMP, etch-back process, combinations thereof, may be then performed to remove the excess conductive material and the mask 97. After the planarization process, the top surfaces of the third ILD 106, the dielectric liners 99, and the source/drain contacts 96 may be substantially coplanar (within process variations).

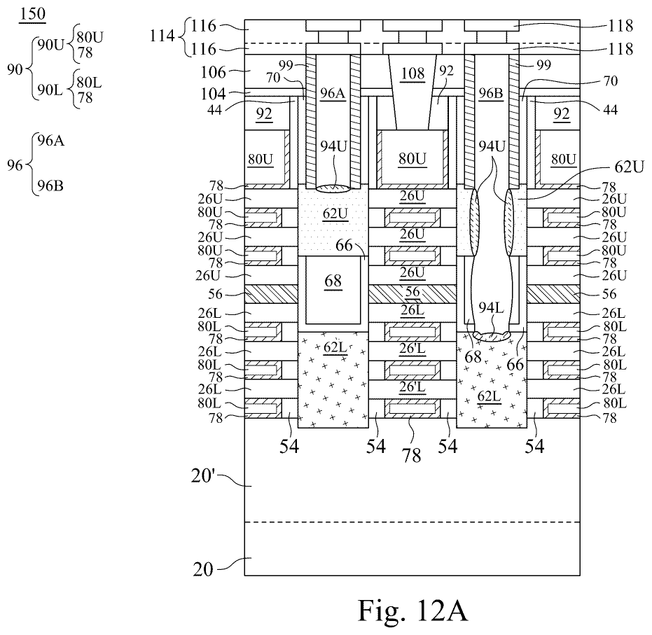

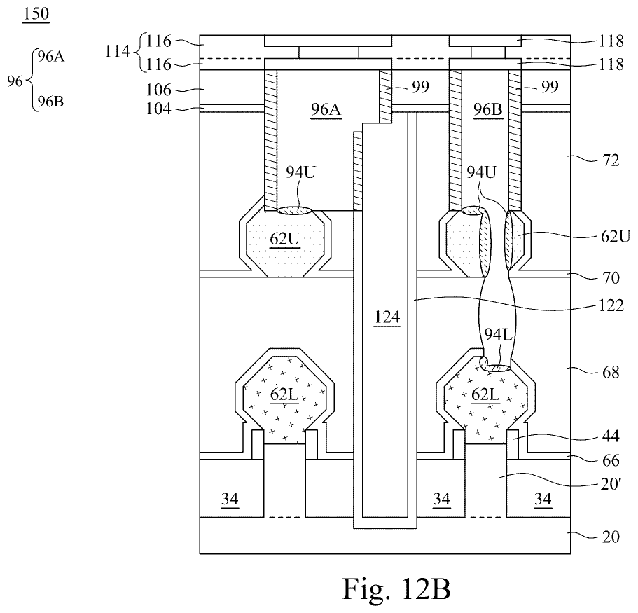

In FIGS. 12A and 12B, gate contacts 108 are formed to contact the upper gate electrodes 80U and a front-side interconnect structure 114 is formed on the third ILD 106. The structure shown in FIGS. 12A and 12B may be referred to as a stacking transistor 150. The cross-sectional view in FIG. 12A may correspond to the cross-sectional view shown in FIG. 11A and the cross-sectional view in FIG. 12B may correspond to the cross-sectional view shown in FIG. 11B. Some of the gate electrodes 80U in FIG. 12A are shown to be without the gate contacts 108 for illustrative purposes, the gate contacts 108 contacting such gate electrodes 80U may be seen in different cross-sections.

The gate contacts 108 may be formed by first forming openings through the third ILD 106, the third CESL 104, and the gate mask 92 by a suitable photolithography process. Then a conductive material may be deposited in the openings by a suitable deposition process, such as ALD, CVD, PVD, or the like. The conductive material may be cobalt, tungsten, copper, silver, gold, aluminum, nickel, or the like. In some embodiments, a conductive liner is deposited in the openings before depositing the conductive material. A planarization process, such as CMP, etch-back process, combinations thereof, may be then performed to remove the excess conductive material. After the planarization process, the top surfaces of the third ILD 106, the dielectric liners 99, the source/drain contacts 96, and the gate contacts 108 may be substantially coplanar (within process variations).

Then the front-side interconnect structure 114 may be formed on the top surfaces of the third ILD 106, the dielectric liners 99, the source/drain contacts 96, and the gate contacts 108. The front-side interconnect structure 114 may include dielectric layers 116 and layers of conductive features 118 in the dielectric layers 116. The dielectric layers 116 may include low-k dielectric layers formed of low-k dielectric materials. The dielectric layers 116 may further include passivation layers formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers. The dielectric layers 116 may be formed by suitable deposition and/or coating processes.

The conductive features 118 may include conductive lines and vias, which may be formed using damascene processes. Conductive features 118 may include metal lines and metal vias, which includes diffusion barriers and a copper containing material over the diffusion barriers. Conductive pads may be over and electrically connected to the metal lines and vias. In subsequent processes (not shown), the substrate 20, include the semiconductor fins 20′, may be replaced by a dielectric layer, and conductive contacts may be formed through the dielectric layer to electrically connect to the lower gate structures 90L, one or more of the lower epitaxial source/drain regions 62L, and the vertical interconnect 124. A backside interconnect (e.g., made of similar materials and processes as the front-side interconnect 114) may then be formed on the opposite side of the stacking transistor 150 as the front-side interconnect 114. The vertical interconnect 124 may electrically connect the conductive features in the front-side interconnect structure 114 to conductive features in the backside interconnect (not shown).

The embodiments of the present disclosure have some advantageous features. By forming the dielectric liners 99 before extending the openings 95B, a risk of damaging the upper epitaxial source/drain regions 62U by a harsher etching process may be reduced. By forming the dielectric liners 99 before extending the openings 95B, areas of the upper metal-semiconductor alloy regions 94U formed on some of the upper epitaxial source/drain regions 62U may be increased, and the resistance between the source/drain contacts 96B and the upper epitaxial source/drain regions 62U, as well as the current crowding effect in the upper epitaxial source/drain regions 62U may be reduced. As a result, the performance and reliability of the stacking transistor 150 may be improved.

In an embodiment, a semiconductor device includes a first dielectric layer; a first source/drain region in the first dielectric layer; a first nanostructure on a sidewall of the first source/drain region; a first gate structure around the first nanostructure; a first conductive contact electrically connected to the first source/drain region, wherein a first portion of the first conductive contact extends through the first source/drain region, and wherein the first portion of the first conductive contact includes a first sidewall and a second sidewall opposite the first sidewall in a cross-sectional view; and a first metal-semiconductor alloy region between the first portion of the first conductive contact and the first source/drain region, wherein a first portion of the first metal-semiconductor alloy region is on the first sidewall and a second portion of the first metal-semiconductor alloy region is on the second sidewall. In an embodiment, the first metal-semiconductor alloy region encircles the first portion of the first conductive contact in a top view. In an embodiment, the first source/drain region encircles the first metal-semiconductor alloy region in the top view. In an embodiment, the first portion of the first metal-semiconductor alloy region is further disposed on a top surface of the first source/drain region. In an embodiment, the first sidewall is concave. In an embodiment, the semiconductor device further includes a second dielectric layer, wherein the first dielectric layer is disposed over the second dielectric layer; a second source/drain region in the second dielectric layer, wherein the first conductive contact electrically connects the first source/drain region to the second source/drain region; and a second metal-semiconductor alloy region between a second portion of the first conductive contact and the second source/drain region. In an embodiment, the first conductive contact and the first dielectric layer are separated by a third dielectric layer, and wherein the second dielectric layer is in contact with the first conductive contact.

In an embodiment, a method of forming a semiconductor includes forming a first nanostructure; growing a first source/drain region, wherein the first nanostructure is on an outer sidewall of the first source/drain region in a cross-sectional view; forming a first gate structure wrapping around the first nanostructure; forming a first opening, wherein the first opening exposes an upper surface of the first source/drain region; depositing a first dielectric layer in the first opening, wherein the first dielectric layer is on a sidewall of the first opening in the cross-sectional view; after depositing the first dielectric layer, removing a first portion of the first source/drain region to extend the first opening, wherein the extended first opening exposes an inner sidewall of the first source/drain region; forming a first metal-semiconductor alloy region on the inner sidewall of the first source/drain region; and forming a first conductive contact in the extended first opening. In an embodiment, the first conductive contact is separated from the first source/drain region by the first metal-semiconductor alloy region. In an embodiment, the method further includes growing a second source/drain region, wherein the second source/drain region is underneath the first source/drain region; and depositing a second dielectric layer, wherein the second dielectric layer is between the first source/drain region and the second source/drain region in the cross-sectional view, and wherein the extended first opening extends through the second dielectric layer and exposes an upper surface of the second source/drain region. In an embodiment, the method further includes forming a second metal-semiconductor alloy region on the upper surface of the second source/drain region, wherein the first conductive contact is separated from the second source/drain region by the second metal-semiconductor alloy region. In an embodiment, a first portion of the first conductive contact extends through the first source/drain region, wherein a second portion of the first conductive contact extends through the second dielectric layer, and wherein the second portion of the first conductive contact is wider than the first portion of the first conductive contact. In an embodiment, a bottom surface of the first dielectric layer is above a top surface of the second dielectric layer. In an embodiment, the method further includes removing a bottom portion of the first dielectric layer on the upper surface of the first source/drain region before removing the first portion of the first source/drain region.

In an embodiment, a method of forming a semiconductor device includes forming a first nanostructure and a second nanostructure over the first nanostructure; growing a first source/drain region on a sidewall of the first nanostructure; depositing a first dielectric layer over the first source/drain region; growing a second source/drain region over the first dielectric layer and on a sidewall of the second nanostructure; depositing a second dielectric layer over the second source/drain region; forming a first gate structure around the first nanostructure and a second gate structure around the second nanostructure; forming a first opening through the second dielectric layer, wherein the first opening exposes an upper surface of the second source/drain region and sidewalls of the second dielectric layer; depositing a third dielectric layer on the upper surface of the second source/drain region and sidewalls of the second dielectric layer; removing a bottom portion of the third dielectric layer to expose the upper surface of the second source/drain region; extending the first opening through the first dielectric layer and into the first source/drain region; and forming a first conductive contact in the extended first opening. In an embodiment, the first dielectric layer is in contact with a first sidewall of the first conductive contact. In an embodiment, the first sidewall of the first conductive contact is convex. In an embodiment, the method further includes simultaneously forming a first metal-semiconductor alloy region and a second metal-semiconductor alloy region, wherein the first metal-semiconductor alloy region is on the first source/drain region, and wherein the second metal-semiconductor alloy region is on the second source/drain region. In an embodiment, the second metal-semiconductor alloy region encircles a first portion of the first conductive contact in a top view. In an embodiment, the second metal-semiconductor alloy region is on the upper surface and a sidewall of the second source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device comprising:
a first dielectric layer;
a first source/drain region in the first dielectric layer;
a first nanostructure on a sidewall of the first source/drain region;
a first gate structure around the first nanostructure;
a first conductive contact electrically connected to the first source/drain region, wherein a first portion of the first conductive contact extends through the first source/drain region, and wherein the first portion of the first conductive contact comprises a first sidewall and a second sidewall opposite the first sidewall in a cross-sectional view; and
a first metal-semiconductor alloy region between the first portion of the first conductive contact and the first source/drain region, wherein a first portion of the first metal-semiconductor alloy region is on the first sidewall and a second portion of the first metal-semiconductor alloy region is on the second sidewall.

2. The semiconductor device of claim 1, wherein the first metal-semiconductor alloy region encircles the first portion of the first conductive contact in a top view.

3. The semiconductor device of claim 2, wherein the first source/drain region encircles the first metal-semiconductor alloy region in the top view.

4. The semiconductor device of claim 1, wherein the first portion of the first metal-semiconductor alloy region is further disposed on a top surface of the first source/drain region.

5. The semiconductor device of claim 1, wherein the first sidewall is concave.

6. The semiconductor device of claim 1, further comprising:
a second dielectric layer, wherein the first dielectric layer is disposed over the second dielectric layer;
a second source/drain region in the second dielectric layer, wherein the first conductive contact electrically connects the first source/drain region to the second source/drain region; and
a second metal-semiconductor alloy region between a second portion of the first conductive contact and the second source/drain region.

7. The semiconductor device of claim 6, wherein the first conductive contact and the first dielectric layer are separated by a third dielectric layer, and wherein the second dielectric layer is in contact with the first conductive contact.

8. A method of forming a semiconductor device, the method comprising:
forming a first nanostructure;
growing a first source/drain region, wherein the first nanostructure is on an outer sidewall of the first source/drain region in a cross-sectional view;
forming a first gate structure wrapping around the first nanostructure;
forming a first opening, wherein the first opening exposes an upper surface of the first source/drain region;
depositing a first dielectric layer in the first opening, wherein the first dielectric layer is on a sidewall of the first opening in the cross-sectional view;
after depositing the first dielectric layer, removing a first portion of the first source/drain region to extend the first opening, wherein the extended first opening exposes an inner sidewall of the first source/drain region;
forming a first metal-semiconductor alloy region on the inner sidewall of the first source/drain region; and
forming a first conductive contact in the extended first opening.

9. The method of claim 8, wherein the first conductive contact is separated from the first source/drain region by the first metal-semiconductor alloy region.

10. The method of claim 8, further comprising:
growing a second source/drain region, wherein the second source/drain region is underneath the first source/drain region; and
depositing a second dielectric layer, wherein the second dielectric layer is between the first source/drain region and the second source/drain region in the cross-sectional view, and wherein the extended first opening extends through the second dielectric layer and exposes an upper surface of the second source/drain region.

11. The method of claim 10, further comprising forming a second metal-semiconductor alloy region on the upper surface of the second source/drain region, wherein the first conductive contact is separated from the second source/drain region by the second metal-semiconductor alloy region.

12. The method of claim 10, wherein a first portion of the first conductive contact extends through the first source/drain region, wherein a second portion of the first conductive contact extends through the second dielectric layer, and wherein the second portion of the first conductive contact is wider than the first portion of the first conductive contact.

13. The method of claim 10, wherein a bottom surface of the first dielectric layer is above a top surface of the second dielectric layer.

14. The method of claim 8, further comprising removing a bottom portion of the first dielectric layer on the upper surface of the first source/drain region before removing the first portion of the first source/drain region.

15. A method of forming a semiconductor device, the method comprising:
forming a first nanostructure and a second nanostructure over the first nanostructure;
growing a first source/drain region on a sidewall of the first nanostructure;
depositing a first dielectric layer over the first source/drain region;
growing a second source/drain region over the first dielectric layer and on a sidewall of the second nanostructure;
depositing a second dielectric layer over the second source/drain region;
forming a first gate structure around the first nanostructure and a second gate structure around the second nanostructure;
forming a first opening through the second dielectric layer, wherein the first opening exposes an upper surface of the second source/drain region and sidewalls of the second dielectric layer;
depositing a third dielectric layer on the upper surface of the second source/drain region and sidewalls of the second dielectric layer;
removing a bottom portion of the third dielectric layer to expose the upper surface of the second source/drain region;
extending the first opening through the first dielectric layer and into the first source/drain region; and
forming a first conductive contact in the extended first opening.

16. The method of claim 15, wherein the first dielectric layer is in contact with a first sidewall of the first conductive contact.

17. The method of claim 16, wherein the first sidewall of the first conductive contact is convex.

18. The method of claim 15, further comprising simultaneously forming a first metal-semiconductor alloy region and a second metal-semiconductor alloy region, wherein the first metal-semiconductor alloy region is on the first source/drain region, and wherein the second metal-semiconductor alloy region is on the second source/drain region.

19. The method of claim 18, wherein the second metal-semiconductor alloy region encircles a first portion of the first conductive contact in a top view.

20. The method of claim 18, wherein the second metal-semiconductor alloy region is on the upper surface and a sidewall of the second source/drain region.
